(19) United States
(12) Patent Application Publication
(10) Pub. No.: US 2025/0389780 A1
(43) Pub. Date: Dec. 25, 2025

(54) Distributed Impedance Measurement System

(71) Applicant: Dynexus Technology, Inc., Loveland, CO (US)

(72) Inventors: Bryan L. Robertus, Bozeman, MT (US); Jon P. Christophersen, Moscow, ID (US); Ty Carlson, Snohomish, WA (US); David J. Sorum, Rhinelander, WI (US)

(73) Assignee: Dynexus Technology, Inc., Loveland, CO (US)

(21) Appl. No.: 18/750,347

(22) Filed: Jun. 21, 2024

(51) Int. Cl. G01R 31/389; G01R 31/367; G01R 31/396

(52) U.S. Cl. CPC G01R 31/389; G01R 31/367; G01R 31/396

(57) ABSTRACT

A distributed impedance measurement system including a cloud based network of servers communicatively coupled through an internet to one or more supervisor controllers each communicatively connected to one or more a sensor pods each configured to connect to and perform an impedance measurement of a device, wherein each supervisor controller receives from the cloud and transfers to one or more sensor pods impedance measurement instructions to deliver an excitation signal to and record a response signal from one or more devices under test and returns the corresponding response signals to the supervisor controller which communicates the response signal to the cloud to perform analysis and return impedance measurement results to one or more client computers.

### I. FIELD OF THE INVENTION

A distributed impedance measurement system including a cloud based network of servers communicatively coupled through an internet to one or more supervisor controllers each communicatively connected to one or more sensor pods each configured to connect to and perform an impedance measurement of a device, wherein each supervisor controller receives from the cloud and transfers to one or more sensor pods impedance measurement instructions to deliver an excitation signal to and record a response signal from one or more devices under test and returns the corresponding response signals to the supervisor controller which communicates the response signal to the cloud to perform analysis or return impedance measurement results to one or more client computers.

### II. BACKGROUND OF THE INVENTION

Conventional impedance measurement of a device involves ex-situ operation of an impedance measurement device which consolidates the hardware in one self-contained device. Typically, the impedance measurement device serially conducts impedance measurement from device to device using a multiplexing system. The use of conventional measurement devices to serially conduct impedance measurements of a plurality of devices can have associated disadvantages of introducing complexity, latency and delay, data errors and data loss.

Conventional battery monitoring through a battery management system (“BMS”) typically senses voltage (“V”), current (“I”), or temperature (“T”). BMS does not perform impedance measurement (“Z”) to extend the concept of resistance (“Ω”) to alternating current (“AC”) circuits including both magnitude and phase over a broad frequency range.

There is a long felt but unresolved need to integrate near real-time broadband impedance measurements on devices throughout the entire life cycle, including as illustrative examples, in-situ diagnostics and prognostics during device manufacturing, device charging, or device operation. There would also be substantial advantages in the use of a distributed hardware architecture that can integrate near real-time broadband impedance measurements on devices to a wide variety of in-situ applications, including batteries used in consumer electronics, telecommunications, automotive, locomotive, and aircraft.

A significant advantage of embodiments of the inventive distributed hardware architecture for broadband impedance measurements can be that the components readily scale with the required environment, whether in a production facility or embedded in the field. In particular applications, the distributed hardware architecture can enable active measurements on a device throughout its entire life cycle. Sensor pods within the inventive hardware architecture can comprise individual components that can be connected or releasably connected to a device within a production facility to conduct impedance measurements during manufacturing of the device. As an illustrative example, the sensor pods can be connected to a battery from formation to end-of-line device qualification, matching or sorting. The impedance measurement(s) can establish a “birth certificate” of the battery that can provide reference impedance measurement(s) for future analysis of the battery state of health, state of stability, and remaining useful life. Sensor pods can also be configured to meet form factor requirements of a device or device location or as an embedded component of an application-specific integrated circuit, such as a battery management system for in-situ battery diagnostics and prognostics. As another illustrative example, sensor pods can be incorporated into a battery charging station to perform impedance measurements during every charge cycle of a battery. The sensor pods can be communicatively coupled directly, or indirectly through a supervisor controller, to a cloud-based network of remote servers using one or more cloud-based algorithm(s) to process the impedance measurement data. The inventive distributed hardware architecture can be implemented to monitor and evaluate an expected expiry of the first use life of a battery or other device, and further evaluate a second use life of the battery or other device. Another advantage of the inventive hardware architecture can be the elimination of a multiplexer system, where impedance measurements are performed sequentially from device to device, rather, the inventive hardware architecture can concurrently perform a plurality of impedance measurements on a plurality of devices rendering concurrent data sets, thus allowing the system to readily scale, reduce production time, and accrue an associated cost savings.

### III. SUMMARY OF THE INVENTION

Accordingly, a broad object of embodiments of the invention can be to provide a distributed impedance measurement system, comprising a cloud-based network of remote servers including a non-transitory computer readable media containing a program code to implement impedance measurement algorithms to measure impedance of a plurality of devices under test and a supervisor controller communicatively coupled over a network to the cloud, wherein the supervisor controller operates to receive impedance measurement instructions from the cloud to measure impedance of the plurality of devices under test, concurrently associate each of the impedance measurement instructions with one of the plurality of devices under test, validate each of the plurality of response signals from each device under test, and send each of said plurality of response signals upon validation to said cloud for analysis and one or more sensor pods communicatively coupled to each supervisor controller, each of the one or more sensors pods operable to receive the impedance measurement instructions associated with one of the plurality of devices under test from the supervisor controller, execute an excitation signal based on said impedance measurement instructions to a device under test, capture a response signal resulting from the excitation signal; and send the response signal to the supervisor to validate and send to the cloud to determine the impedance of the device under test. In particular embodiments the invention a fixture can be communicatively coupled to each of the one or more sensor pods, wherein the fixture has a configuration to operably engage one of the plurality of devices under test to deliver the excitation signal to said device under test and capture the response signal from said device under test.

Another broad object of embodiments of the invention can be a method of making a distributed impedance measurement system including communicatively coupling a cloud-based network of remote servers over a network to one or more supervisor controllers, each supervisor controller configured to: receive impedance measurement instructions from the cloud to measure impedance of a plurality of devices under test, concurrently associate each of the impedance measurement instructions with one of the plurality of devices under test, validate each of the plurality of response signals from each of the plurality of devices under test, and send upon validation each of the plurality of response signals to the cloud for analysis, and communicatively coupling one or more sensor pods to each supervisor controller, each of the one or more sensor pods operable to receive the impedance measurement instructions associated with one of the plurality of devices under test from the supervisor controller, execute an excitation signal based on said impedance measurement instructions to a device under test, capture a response signal resulting from the excitation signal; and send the response signal to the supervisor to validate and send to the cloud to determine the impedance of the device under test. In particular embodiments the method can further include communicatively coupling a fixture can to each of the one or more sensor pods, wherein the fixture has a configuration to operably engage one of the plurality of devices under test to deliver the excitation signal to said device under test and capture the response signal from said device under test.

Another broad object of embodiments of the invention can be a method of using a distributed impedance measurement system, the method including one or more of: serving impedance measurement instructions from a cloud-based remote server over a network to one or more supervisor controllers, each of the supervisor controllers performing one or more of: receiving the impedance measurement instructions to measure impedance of a plurality of devices under test, concurrently associating each of the impedance measurement instructions with one of the plurality of devices under test, concurrently associating each of a plurality of response signals based on said impedance measurement instructions with one of said plurality of devices under tests, validating each of the plurality of response signals from the plurality of devices under test, sending each of the plurality of response signals for analysis to the cloud; and transferring the impedance measurement instructions to one or more sensor pods communicatively coupled to the supervisor, each of the one or more sensors pods performing one or more of: receiving the impedance measurement instructions associated with one of said plurality of devices under test from the supervisor, delivering an excitation signal based on said impedance measurement instructions to the device under test, capturing a response signal resulting from delivery of the excitation signal; and sending the response signal to the supervisor. In particular embodiments the method can further include communicatively coupling a fixture can to each of the one or more sensor pods, operably engaging the fixture to one of the plurality of devices under test to deliver the excitation signal to the device under test and capture the response signal from the device under test.

Naturally, further objects of the invention are disclosed throughout other areas of the specification, drawings, photographs, and claims.

### IV. BRIEF DESCRIPTION OF THE DRAWINGS

FIG. 1 is a block flow diagram illustrating the general relationship of the components of an embodiment of the inventive distributed hardware system to measure impedance of a plurality of devices under test.

FIG. 2A is a block flow diagram illustrating a particular embodiment of the system including a plurality of sensor pods connected in a parallel circuit.

FIG. 2B is a block flow diagram illustrating a particular embodiment of the system including a plurality of sensor pods connected in a series circuit.

FIG. 2C is block flow diagram illustrating a particular embodiment of the system wherein a first plurality of sensor pods and a second plurality of sensor pods each connected in individual parallel circuits, and wherein the first and second plurality of sensor pods connected in parallel circuits are than connected in a series circuit.

FIG. 2D is a block flow diagram illustrating a particular embodiment of the system including four sensor pods in which three of the four sensor pods are connected in series and one sensor pod operates independently of the three sensor pods connected in the series circuit.

FIG. 3 is a block diagram illustrating a particular embodiment of a cloud-based server of the system including a processor communicatively coupled to a non-transitory computer readable media containing a program code for implementing algorithms to implement the impedance measurement of one or more devices under test.

FIG. 4 is a block diagram illustrating a particular embodiment of a supervisor controller of the system including a processor communicatively coupled to a non-transitory computer readable media containing a program code to implement the impedance measurement of one or more devices under test.

FIG. 5 is a block diagram illustrating a particular embodiment of a sensor pod of the system including a processor communicatively coupled to a non-transitory computer readable media containing a program code to implement the impedance measurement of one or more devices under test.

FIG. 6 is a block flow diagram generally illustrating a flow of data packets between the cloud and the supervisor controller.

FIG. 7 is a block flow diagram generally illustrating a flow of data packets between the supervisor controller and the cloud and between the supervisor controller and the sensor pod.

FIG. 8 is a block flow diagram generally illustrating the flow of data packets between the sensor pod and the supervisor controller and the sensor pod and the device under test.

FIG. 9 is a block flow diagram generally illustrating the flow of data packets in the system.

FIG. 10 is a block flow diagram which illustrates the operation of the cloud in a particular embodiment of the system.

FIG. 11 is a block flow diagram which illustrates the operation of a supervisor controller in a particular embodiment of the system.

FIG. 12 is a block flow diagram which illustrates the operation of a sensor pod in a particular embodiment of the system.

### V. DETAILED DESCRIPTION OF THE INVENTION

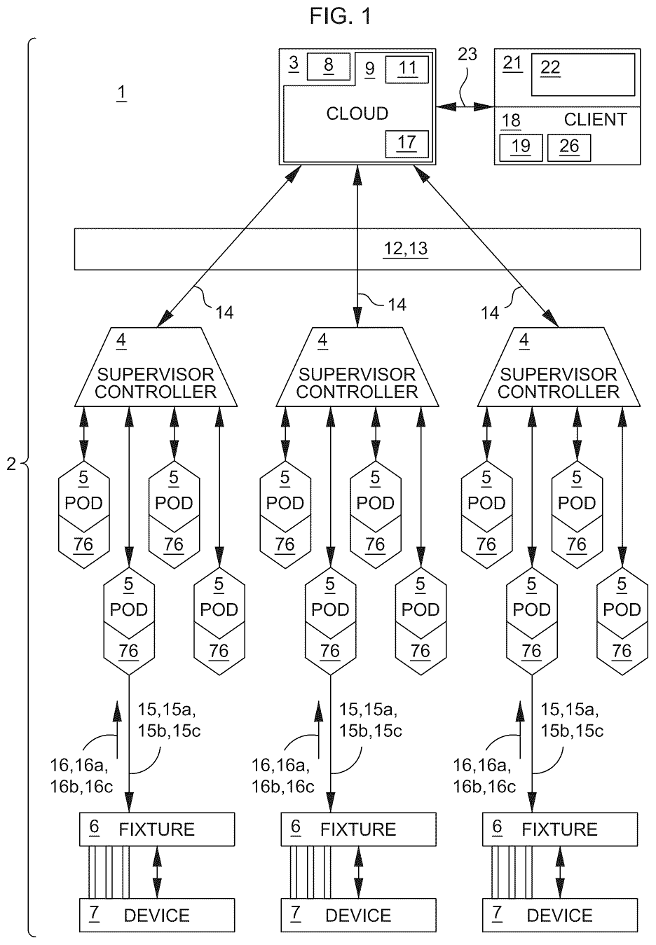

Generally, referring to FIGS. 1 through 10, the inventive impedance measurement system (1) (also referred to as the “system”) comprises a distributed hardware architecture (2), including one or more of: a cloud-based network of remote servers (3) (also referred to as the “cloud”); a supervisor controller (4) communicatively coupled to the cloud (3); a sensor pod (5) communicatively coupled to the supervisor controller (4); and a fixture (6) communicatively coupled to the sensor pod (5) and configured to operably engage a device (7).

Now, with primary reference to FIG. 1, which depicts the overall relationship of the hardware components in an illustrative embodiment of the distributed hardware architecture (2) in the system (1). The cloud (3) can comprise a cloud-based network of remote servers each including processor (8) communicatively coupled to a server non-transitory computer readable media (9) containing in whole or in part a cloud program code (10) which can be served to implement one or more impedance measurement algorithms (11) to measure impedance of a device (7) under test. The supervisor controller (4) can be communicatively coupled to the cloud (3) over a wide area network (12) (“WAN”), such as the Internet, or one or more local area networks (13) (“LAN”) to receive impedance measurement instructions (14) to implement impedance measurement of one or a plurality of devices (7) under test. The supervisor controller (4) can concurrently associate each of a plurality of impedance measurement instructions (14) with one of the plurality of devices (7) under test to generate an excitation signal (15) and correspondingly concurrently associate each response signal (16) resulting from the excitation signal (15) with one of the plurality of devices (7) under test. The supervisor controller (4) can further operate to validate each of a plurality of response signals (16) and upon validation send each of the plurality of response signals (16) to the cloud (3) for analysis. One or more sensor pods (5) can be communicatively coupled to each supervisor controller (4), each of the one or more sensors pods (5) can operate to receive an impedance measurement instruction (14), or other test instruction, associated with a device (7) under test, deliver an excitation signal (15) based on the impedance measurement instructions (14) to the device (7), and capture a response signal (16) resulting from the excitation signal (15) delivered to the device (7). Each of the sensor pods (5) can send a record of the response signal (16) to the supervisor controller (4). In particular embodiments, a device (7) under test can be engaged by a fixture (6) communicatively coupled to one or more sensor pods (5).

In describing embodiments of the inventive distributed hardware architecture (2); elements, circuits, modules, and functions may be shown in block diagram form. Moreover, specific implementations shown and described are illustrative only and should not be construed as the only way to implement the present disclosure unless specified otherwise herein. Additionally, block definitions and partitioning of logic between various blocks is illustrative of a specific implementation. However, the present disclosure may be practiced by numerous other partitioning solutions. For the most part, details concerning timing considerations and the like have been omitted where such details are not necessary to obtain a complete understanding of the present disclosure by persons of ordinary skill in the relevant art.

Those of ordinary skill would appreciate that the various illustrative logical blocks, modules, circuits, and algorithm described in connection with embodiments disclosed herein may be implemented as electronic hardware, computer software, or combinations of both. To clearly illustrate this interchangeability of hardware and software, various illustrative components, blocks, modules, circuits, and acts are described generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the embodiments described herein.

In addition, it is noted that the embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a function, a procedure, a subroutine, a subprogram, or a step depending on the application. Furthermore, the methods disclosed herein may be implemented in hardware, software, or both. If implemented in software, the functions may be stored or transmitted as one or more instructions or code on a non-transitory computer-readable medium. Computer-readable media includes both computer storage media and communication media including any medium that facilitates transfer of a computer program from one place to another.

It should be understood that any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed or that the first element must precede the second element in some manner. In addition, unless stated otherwise, a set of elements may comprise one or more elements.

Electrochemical Impedance Spectroscopy. Generally, electrochemical impedance spectroscopy (EIS) measurements (17) involve measuring a response signal (16) to an excitation signal (15). This excitation signal (15) can be a current excitation signal (15a) or a voltage excitation signal (15b) with the response signal (16) measure being the complement (for example, if the excitation signal (15) is an alternating current excitation signal (15a) then the response can be an alternating current voltage response signal (16b), if the excitation signal (15) is a voltage excitation signal (15b) then the response signal (16) can be a current response signal (16a). Data processing then calculates the complex impedance of each device (7) at the excitation signal frequency (15c). This process is generally performed at each of a plurality of frequencies (15c′, 15c″, 15c′″ . . . ) to create an array of complex impedances. Conventional EIS produces impedance measurements (17) that typically have a range from about 100 kHz to about 10 mHz and may take an amount of time in the range of about ten minutes to about an hour to perform depending on impedance measurement instructions (14).

In the distributed hardware architecture (2) using in-line rapid impedance spectroscopy (“IRIS®”) with cloud-based analytics, a plurality of concurrent impedance measurements (17) on a plurality of devices (7) at about 10 kHz to about 10 mHz in a time interval of about 1 sec to about 100 sec depending on the impedance measurement instructions (14). As illustrative examples, embodiments of the invention, can utilize a plurality of sensor pods (5) to concurrently perform impedance measurements (17) on a plurality of devices (7) in a range of about 9.5 mHz to about 10 kHz in about 105 sec, from about 0.076 Hz to about 10 kHz in about 10 sec, or from about 1.2 Hz to about 10 kHz in about 1.0 sec, or incrementally between a start frequency of about 9.5 mHz to end frequency of about 10 kHz, or in combinations thereof.

In particular embodiments, the inventive distributed hardware architecture (2) can include additional cloud-based metrics for enhanced in-situ (or ex-situ) device screening, device qualification, device sorting, device matching, device binning, first use application (FUA), device state-of-health (SOH), device state-of-stability (SOS), or device remaining useful life (RUL), device end of life (EOL). The sensor pods (5) can each deliver an excitation signal (15) including a sum of sinusoids over a broad frequency range within one period of the lowest frequency to the device (7) under test and capture the response signal (16). Particular embodiments of inventive distributed hardware architecture (2) are capable of impedance measurement on batteries of up to about 240V with impedance down to about 0.25 mΩ at about 10 μΩ resolution. The measurable battery impedance can be lowered to approximately 0.1 mΩ with about ±1 μΩ resolution if the maximum upper voltage threshold is reduced to about 30V.

Thus, the system (1) including the distributed hardware architecture (2) and the cloud program code (10) has been developed for high resolution capability, measurement accuracy, and measurement repeatability. These enhancements enable higher levels of detectability in both SOH and SOS as a function of battery aging and use.

### The Distributed Impedance Measurement Architecture.

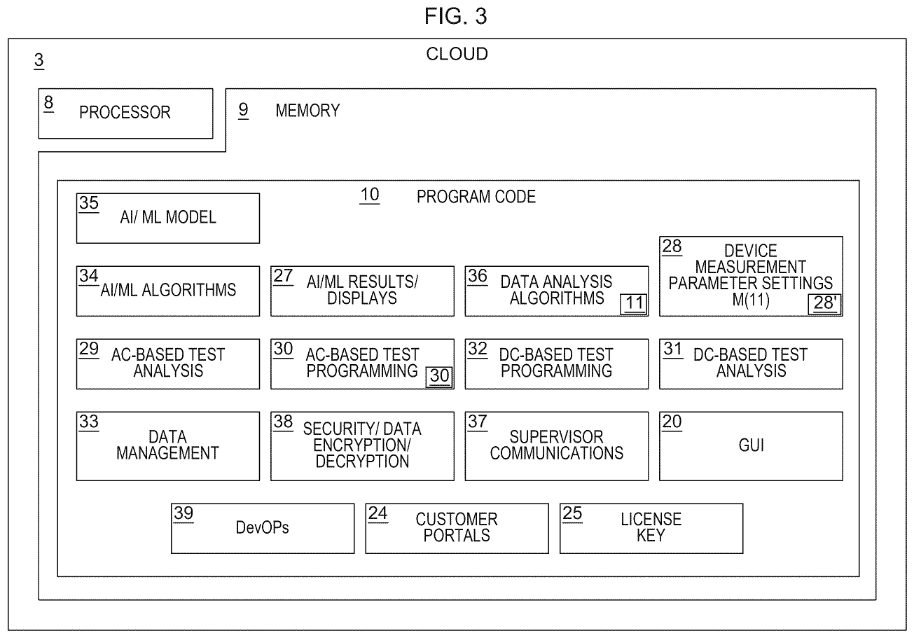

The Cloud. Now, with primary reference to FIGS. 1 and 3, embodiments of the invention can include a cloud-based network of servers (3) which operate as a single ecosystem to store and manage data, run applications, or deliver content. The cloud-based network of remote servers (3) whether operating independently or in combination afford a processor (8) communicatively coupled to a server non-transitory computer readable media (9) containing a cloud program code (10) to implement data analysis algorithms (11) to generate an impedance measurement (17), or other measurement, of one device (7) or concurrently generate impedance measurements (17), or other measurements, of a plurality of devices (7) under test.

Client Computers. One or more client computers (18) can each be configured to connect with one or more server computers of the cloud (3) through one or more wide area networks (12) (WAN), such as the Internet, or one or more local area networks (13) (LAN) to transfer digital data. The client computer (18) can, as to particular embodiments, take the form of a limited-capability computer designed specifically for navigation of a WAN (12) such as the Internet. However, the invention is not so limited, and the client computer (18) can be as non-limiting examples: set-top boxes, hand-held devices such as smart phones, slate or pad computers, personal digital assistants or camera/cell phones, or multiprocessor systems, microprocessor-based or programmable consumer electronics, network personal computers, minicomputers, mainframe computers, or the like.

The client computer (18) can include a browser (19) such as GOOGLE CHROME®, MOZILLA®, FIREFOX®, or the like, which functions to download and render multimedia content that is formatted in “hypertext markup language” (HTML). In this environment, the cloud program code (10) includes a graphical user interface module (20) (“GUI module”) that implements the most significant portions of a graphical user interface (21) which can include one or a plurality of screen displays (22) generated by execution of the GUI module (20). The one or more client computers (18) can use the browser (19) to display downloaded content and to relay user inputs (23) back to the one or more servers of the cloud (3). The one or more servers of the cloud (3) can respond by formatting new screen displays (22) of the graphical user interface (21) and downloading them for display on the client computer (18) in an aspect ratio and layout appropriate for that form factor.

In particular embodiments, the cloud program code (10) includes a customer portal module (24) which enables each of a plurality of client computers (18) having permissions afforded by a license key module (25) actuated by use of a virtual key (26) access to the cloud (3) and the data associated within the permissions of the virtual key (26). Thereby each client computer (18) gains access to virtual key associated data without gaining access to data associated with other client computers (18).

In particular embodiments, through the GUI module (20) a client computer (18) can gain access to one or more of: an artificial intelligence/machine learning results display module (27) (“AI/ML results display module”), an impedance spectroscopy parameters setting module (28) (“IS parameter setting module”), an alternating current based test analysis module (29) (“AC-based test analysis module”), an alternating current based test programming module (30) (“AC-based test programming module”), a direct current based test analysis module (31) (“DC-based test analysis module”), a direct current test programming module (32) (“DC-based test programming module”), and a data management module (33).

Again, with primary reference to FIG. 3, in particular embodiments, the cloud program code (3) can include an artificial intelligence/machine learning algorithms module (34) (“AI/ML algorithms module”) executable to process sensor pod response signals (16) against specified criteria. As an illustrative example, in battery manufacturing applications, the AI/ML algorithms module (34) can be implemented to process sensor pod response signals (16) for screening during battery formation, cell acceptance, cell ranking, or for cell matching in the assembly of battery modules, or battery packs as described by U.S. Pat. No. 11,519,969, hereby incorporated by reference in the entirety herein. As a further illustrative example, during battery operation, the AI/ML algorithms module (34) can be executed to access battery use data and associated metadata to assess state-of-health (SOH), state of charge (SOC), state of stability or safety (SOS), remaining useful life (RUL) and/or access battery charging or battery fast charging algorithms to match battery charging protocols to the current battery state. In particular embodiments, the AI/ML algorithms module (34) can take all of the relevant battery historical data combined with point-in-time measurement(s) to qualify or certify the battery for a second-use application (SUA).

Again, with primary reference to FIG. 3, in particular embodiments, an artificial intelligence/machine learning model (35) (“AI/ML Model”) can be created by using processed sensor pod response signals (16) (also referred to as “sensor pod data”) with known results as “training data” for use by the artificial intelligence/machine learning algorithm module (34). The sensor pod data (16) used in training may be as small as a few hundred rows of data but can be a few thousand rows of data. The AI/ML algorithm module (34) can comprise neural networks, typically a group of algorithms, used to certify the underlying relationships in the sensor pod data (16), but other techniques such as iterative random forests for classification or regression may be used. The AI/ML learning algorithm module (34) can use the training sensor pod data (16) to build predictive models which comprise mathematical formula using covariates from the training sensor pod data (16) to recognize certain patterns, make decisions, or perform tasks. When new sensor pod data (16) is collected, it can be applied to the AI/ML model (35) and the response can be a predictive result.

The AI/ML results display module (27) renders the AI/ML model (35) accessible by the client computers (18) by operation of the customer portal module (24) to afford models, measurement settings, and results of AI/ML models (35), which can be in a “white box” or “glass box” format providing a result with clearly readable rules about the factors influencing its decision process. In particular embodiments, the client computer (18) can be utilized to change the rules or boundary conditions to adjust the decision process.

Again, with primary reference to FIG. 3, embodiments of the cloud program code (10) can include device measurement parameters setting module (28) accessible by a client computer (19) to establish the EIS and/or IRIS measurement parameters (28′) for the device (7) under test which can include one or more of: excitation signal frequency number, excitation signal frequency range, excitation signal level, excitation signal negative time, excitation signal type, excitation signal triggers. The EIS and/IRIS measurement parameters (28′) can be responsive to the device (7) performance and assessment by the AI/ML model (35). As an illustrative example, if the AI/ML model (35) detects a battery condition which deviates in comparison to a control or standard, the EIS and/or IRIS measurement parameters (28′) can be adjusted to enable rapid-fire, short duration EIS/IRIS measurements to observe changes and, if necessary, issue warning messages as described in U.S. Pat. Nos. 11,422,102 and 11,714,056, each hereby incorporated by reference in the entirety herein.

Again, with primary reference to FIG. 3, embodiments of the cloud program (3) can include an AC-based test programming module (30) accessible by a client computer (18) to establish AC-based measurement parameters (30′) of a device (7) under test, such as parameters for AC internal resistance measurements of the device (7) under test. The AC-based measurement parameters (30′) which can be set include one or more of: excitation signal frequency number, excitation signal frequency range, excitation signal level, excitation negative time, excitation signal type, excitation signal triggers.

Again, with primary reference to FIG. 3, embodiments of the cloud program (3) can include DC-based test programming module (32) accessible by a client computer (18) to establish DC-based measurement parameters (32′), including current excitation levels, current pulse duration, charge/discharge rate, to measure as one example, direct current internal resistance (“DCIR”).

Again, with primary reference to FIG. 3, embodiments of the cloud program code (3) can include an impedance data analysis algorithms module (36) which can be implemented to process sensor pod response data (16), such as broadband AC-impedance data, resulting from excitation of a device (7) under test. The data analysis algorithms module (36) can include data analysis algorithms (11) to process the sensor pod response data (16) to generate broad band impedance measurements (17) including one or more AC impedance measurements, including, but not necessarily limited to, harmonic compensated synchronous detection (“HCSD”), fast summation transformation (“FST”), time cross talk compensation (“TCTC”), and harmonic orthogonal synchronous transformation (“HOST”), chirp, and step chirp group, as described in WO Publication No. 2020/223630, hereby incorporated by reference in the entirety herein. In particular embodiments, the impedance data analysis algorithms (11) can be configured to analyze the impedance data resulting from the use of IRIS as described in U.S. Pat. No. 11,422,102, hereby incorporated by reference herein. In one embodiment, the response signal (16) resulting from the executed excitation signal (15) and captured by a sensor pod (5) can be uploaded to the cloud (3) by operation of the supervisor controller (4) for data analysis. In other embodiments, a part or all the data analysis algorithms (11) can be transferred from the cloud (3) to the supervisor controller (4) and data analysis can be performed by the supervisor controller (4), and the cloud (3) can receive the analyzed sensor pod response data (16). In either embodiment, the sensor pod response data (16) can be transferred to the AI/ML algorithm module (34) for analysis.

Again, with primary reference to FIG. 3, in particular embodiments, the cloud program (3) can include an AC-based test analysis module (29) which can further include AC-based data analysis algorithms (29′) to process the sensor response data (16) resulting from the use of alternative or future iterations of AC-based impedance measurement parameters (30′). As an example, the AC-based data analysis algorithms can be useful for analysis of EIS and/or IRIS measurements in the development of EIS and/or IRIS protocols, or analysis of data from the use of alternating current internal resistance (“ACIR”).

Again, with primary reference to FIG. 3, in particular embodiments, the cloud program code (3) can include a DC-based test analysis module (31). The DC-based test analysis module (31) can include DC-based data analysis algorithms (31′) to process the sensor pod response data (16) associated with DC-based test parameters (32′), including, but not necessarily limited to data analysis algorithms to analyze pulse profiles, charge/discharge rate, and/or DCIR.

Again, with primary reference to FIG. 3, embodiments of the cloud program (3) can include a data management module (33) executable by a client computer (18) to gain access to a repository of sensor pod data (16) and AI/ML model (35) assessments of device (7) tests which can be used to trace condition of a device (7) and to compare present device state against one or more prior device states including as an example the device states associated with the device birth certificate.

Again, with primary reference to FIG. 3, embodiments of the cloud program code (10) can include a supervisor communications module (37) which enables the cloud-based network of servers (3) to send data packets to the supervisor controller (4) and for the supervisor controller (4) to receive the data packets from the cloud-network of servers (3) including AC-impedance measurement type or DC-measurement type, and AC-based or DC-based excitation signal parameters for the device under test. The supervisor communications module (37) also enables the supervisor controller (4) to send back sensor pod data (16) from measurements of the device (7) under test to the cloud (3) including all associated metadata captured by the sensor pods (5).

Again, with primary reference to FIG. 3, embodiments of the cloud program code (10) can include a data encryption/decryption module (38) which operates to protect against unauthorized access to the data being transmitted or received by the cloud (3). The data encryption/decryption module (38) operates to decrypt data from the supervisor controller (4) and encrypt the data for transfer to the supervisor controller (4).

Again, with primary reference to FIG. 3, embodiments of the cloud program code (3) can further include a development and operations module (39) (“DevOPs module”) to enable one or more client computers (18) to perform overall management of the sensor pod data (16) being collected by a plurality of pods (5) to investigate and resolve technical issues and increase efficiency, productivity and speed within the system (1). In particular embodiments, the DevOPS module enables management of the program code base and versions of the code, version sets, installed on various components of the system (1).

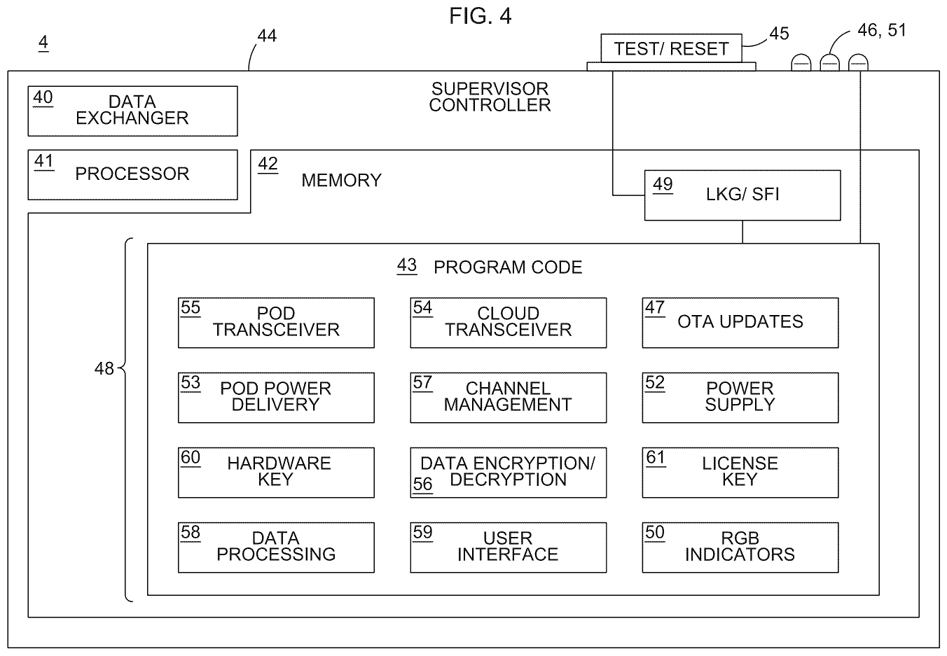

The Supervisor. Now, with primary reference to FIG. 4, embodiments of system (1) can include a supervisor controller (4). In particular embodiments, the supervisor controller (4) can comprise a rack-mount unit that operates to coordinate operation of one or a plurality of pods (5) communicatively coupled to the supervisor controller (4). The supervisor controller (4), can include one or more of: a data exchanger (40) operable to exchange data over a network (12, 13) with the cloud (3) and with each of the plurality of pods (5), a supervisor controller processor (41) can be communicatively coupled to a supervisor controller non-transitory computer readable media (42) containing a supervisor controller program code (43) disposed in read only memory and/or random access memory, which can be contained in a supervisor controller encasement (44) affording a user accessible supervisor controller reset feature (45), one or more user viewable or audible, whether directly or remotely, supervisor controller status indicators (46).

Again, with primary reference to FIG. 4, the supervisor controller program code (43) can include a firmware update module (47) which implements a firmware update of the supervisor controller firmware (48). In particular embodiments, the firmware update module (47) operates to enable over-the-air (“OTA”) updates. In particular embodiments, the supervisor controller program code (43) includes a last known good/signed factory image module (49). If a firmware update does not successfully install, the last known good/signed factory image module (49) can function to roll back to a bootable last known good image of the supervisor controller firmware (48). Operation of the supervisor controller reset feature (45) instructs a last known good/signed factory image module (49) to copy the signed factory image of the supervisor controller firmware (48) to a limited access memory boot address.

Again, with primary reference to FIG. 4, the supervisor controller computer program (43) can include a supervisor controller status indicator module (50) which functions to control operation of viewable or audible supervisor controller status indicators (46). As an illustrative example, the supervisor controller status indicators (46) can comprise light emitters (51) coupled to the supervisor controller encasement (44). The light emitters (51) can comprise light emitting diodes of various colors which can be operated independently or in various combinations or periodicity to indicate the status of the supervisor controller (4), such as: power indication, error warning indication, ongoing test(s) indication, tests completed indication, cell sorting results or data status, such as: impedance measurements results indication, device matching or sorting results indication.

Again, with primary reference to FIG. 4, the supervisor controller computer program (43) can further include a supervisor controller power management module (52) operable to regulate power to the components of the supervisor controller (4). The supervisor controller (4) integrated into the distributed hardware architecture (2) can coordinate power from one source or from a plurality of sources individually, concurrently or in various combinations including as illustrative examples: mains electric power, wall power, energy storage power, power over the Ethernet, or the device (7) under test.

In particular embodiments, the supervisor controller program (4) can further include a pod power delivery module (53) to regulate power to each of a plurality of sensor pods (5) from the one or the plurality of power sources to implement operation of each of the plurality of sensor pods (5).

Again, with primary reference to FIG. 4, embodiments of the supervisor controller (4) can be communicatively coupled to the cloud (3). The supervisor controller program code (43) can further include a cloud data exchanger (54) operable to transfer information between the cloud (3) and the supervisor controller (4). As one example, the supervisor controller data exchanger (40) operates to receive one or more impedance measurement instructions (14) from the cloud (3) which are implemented to configure the excitation signal (15) to deliver to the device (7) under test and to send response signals (16) from one or more devices (7) under test to the cloud (3) to determine impedance of each of the plurality of devices (7) under test. The supervisor controller program code (43) can further include a sensor pod data exchanger (55) operable to transfer information between the supervisor controller (4) and one or more of the sensor pods (5). As an example, the sensor pod data exchanger (54) operates to receive impedance measurement instructions (14) which can include one or more of excitation signal frequency number, excitation signal frequency range, excitation signal level, excitation signal negative time, excitation signal type, and excitation signal triggers.

Again, with primary reference to FIG. 4, in particular embodiments, the supervisor computer program code (43) can further include a supervisor controller data encryption-decryption module (56) operable to decrypt data from each of the plurality of sensor pods (5) and encrypt the data for transmission to the cloud (3). The encryption-decryption of data can protect against reverse engineering of the supervisor controller firmware or any data associated with the impedance measurement(s) of a device(s) under test, including as examples, settings, parameters, triggers. In particular embodiments, data associated with the impedance measurement(s) can be placed in random access memory with random memory address offsets to ensure that the specific data are not reverse engineered.

Again, with primary reference to FIGS. 1 and 4, the supervisor controller (4) can concurrently associate each of the one or more impedance measurement instructions (14) with a corresponding one of the plurality of devices (7) under test to allow a sensor pod (5) to deliver an excitation signal (16) to one of the plurality of devices (7) under test based on the associated impedance measurement instruction (14) and concurrently associate each of a plurality of response signals (16) captured by a plurality of sensor pods (5) with one of the plurality of devices (7) under test. The supervisor controller (4) can further operate to validate each of the plurality of response signals (16) and upon validation send each of said plurality of response signals (16) to the cloud (3) for analysis.

In particular embodiments, the supervisor controller program code (4) can include a channel management module (57) operable to enable communication, concurrent communication, or simultaneous communication with a plurality of sensor pods (5). In certain instances, the supervisor controller (4) can send simultaneously, concurrently or in staggered periods, the same impedance measurement instructions (14) to each one of a plurality of sensor pods (5). In other instances, the supervisor controller (4) can send simultaneously, concurrently or in staggered periods, different impedance measurement instructions (14) to each one of a plurality of sensor pods (5).

In particular embodiments, the supervisor controller (4) operates to pass-through data between the sensor pods (5) and the cloud (3), with minimal data processing. In other particular embodiments, the supervisor controller (4) can include a supervisor controller data processing module (58) configured to afford data processing capabilities, such as a field programmable gate array (“FPGA”), and process sensor pod response data (16) (AC-based measurement data or DC-based measurement data) prior to sending the data to the cloud (3). The supervisor controller (4) may also contain storage for data retention permanently or for a set period of time.

One or more client computers (18) can each be configured to connect with one or more supervisor controllers (4) directly or through the cloud (3) through one or more wide area networks (12) (WAN), such as the Internet, or one or more local area networks (13) (LAN) to transfer digital data. In particular embodiments, the supervisor program code (43) can include independent of, or downloaded from the cloud (3), whether in whole or in part a supervisor controller graphical user inface module (59) which operates in part to display a graphical user interface (21) including screens formatted to enable a client computer (18) access to one or more supervisor controllers (4) within the scope of permissions afforded by one or both of a hardware key module (60) and/or a license key module (61) through use of corresponding virtual keys (26). Thereby, each client computer (18) connects to the supervisor controller (4) within the scope of permissions granted by the license key module (61) and gains authorized access within the scope of permissions granted by the hardware key module (60) to the supervisor controller application interface between the sensor pods (5) and the cloud (3).

The Pod. Now, with primary reference to FIGS. 1, 2A through 2D and 5, embodiments of the sensor pod (5), include one or more of: pod sensors (76), a sensor pod data exchanger (62) operable to exchange data with the supervisor controller (4), a sensor pod processor (63) communicatively coupled to a pod non-transitory computer readable media (64) containing a sensor pod program code (65) disposed in read only memory or random access memory, which can be contained in a sensor pod encasement (66) affording a user accessible sensor pod reset feature (67), one or more user viewable or audible pod status indicators (68), and a device interface configured to engage a device (7) under test, whether directly or through a fixture (6). Sensor pods (5), whether configured to engage or release from a device (7) or comprise an embedded component, can stand alone, or be connected in series, in parallel, or in parallel and in series to adjust the voltage excitation signal (15b) and/or current excitation signal (15a) to conform to the of the device(s) (7) under test.

Now, with primary reference to FIG. 1, as an illustrative example, each of four sensor pods (5) can be configured to measure impedance of a device up to 20V with 2A root mean square current excitation (15a), then the sensor pods can be used to concurrently measure impedance of four independent devices (7) that are within the voltage and current constraints of each of the four sensor pods (5).

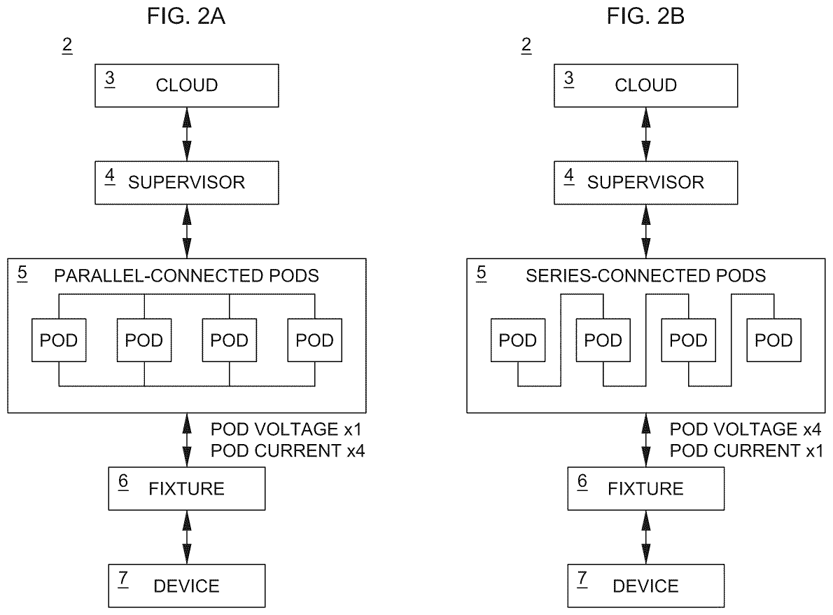

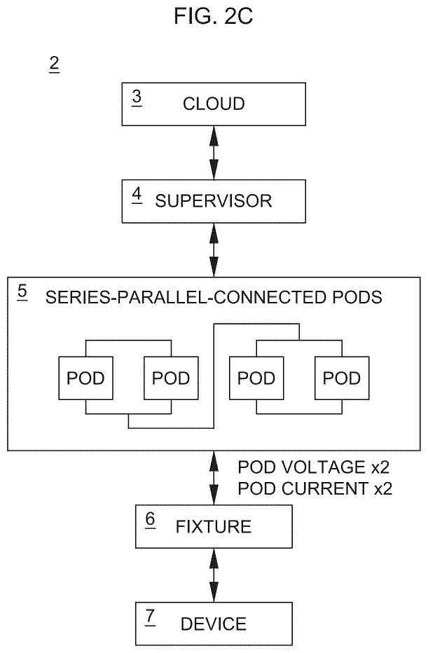

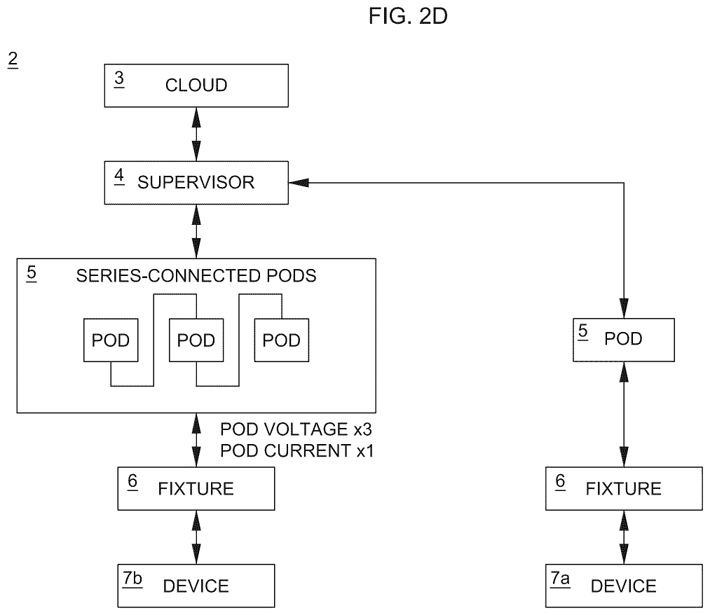

Now, with primary refence to FIG. 2A, as an illustrative example, each sensor pod (5) can be configured to measure impedance of a device up to 20V with 2 A root mean square current excitation (15a), however, the excitation current of the device (7) under test has a voltage within the range of each sensor pod (5) but requires an excitation current (15a) of 8 A RMS. In this illustrative example, four sensor pods (5) can be connected in a parallel configuration to achieve the appropriate voltage of 20V and provide an excitation current of 8 A RMS.

Now, with primary refence to FIG. 2B, as an illustrative example, each sensor pod (5) can be configured to measure impedance of a device up to 20V with 2 A root mean square current excitation (15a), however, the device (7) under test has an excitation current within the range of each sensor pod (5) but requires a voltage of 80V. In this illustrative example, four sensor pods (5) can be connected in a series configuration to achieve the appropriate voltage of 80V and provide an excitation current of within the range of each sensor pod (5).

Now, with primary reference to FIG. 2C, as an illustrative example, each sensor pod (5) can be configured to measure impedance of a device (7) up to 20V with 2 A root mean square current excitation (15a), however, the device (7) under test requires an excitation current of 4 A RMS and the device voltage is 40V. In this illustrative example, each of two pairs of sensor pods (5) can be connected in parallel to achieve the excitation current (15a) of 4 A and each of the two pairs pods (5) connected in parallel can be connected in series to achieve the voltage of 40V.

Now, with primary reference to FIG. 2D, as an illustrative example, each sensor pod (5) can be configured to measure impedance of a device up to 20V with 2 A root mean square current excitation (15a), however, two devices (7) are being concurrently tested, wherein a first device (7a) under test is with in the limits of 20V and 2 A root mean square current excitation, and wherein a second device (7b) under test requires a voltage of 60V and an excitation current of 2 A RMS. In this illustrative example, three sensor pods (5) can be connected in series to achieve a voltage of 60V and an excitation current of 2 A to measure impedance of the second device (7b), and the fourth pod (5) can be used to measure impedance of the first device (7a).

The above examples do not preclude other configurations of sensor pods (5) in which a plurality of pods can be connected in series, or in which a plurality of sensor pods (5) can be connected in parallel, or in which a first plurality of sensor pods (5) connected in parallel and second plurality of sensor pods (5) connected in parallel can then be connected in series to meet the current excitation and voltage requirements that can vary between device(s) (7) under test. The use of four sensor pods (5) in the examples is merely illustrative; and any number of sensor pods (5) can be utilized in various configurations depending on the voltage and current requirements of the device(s) (7) under test.

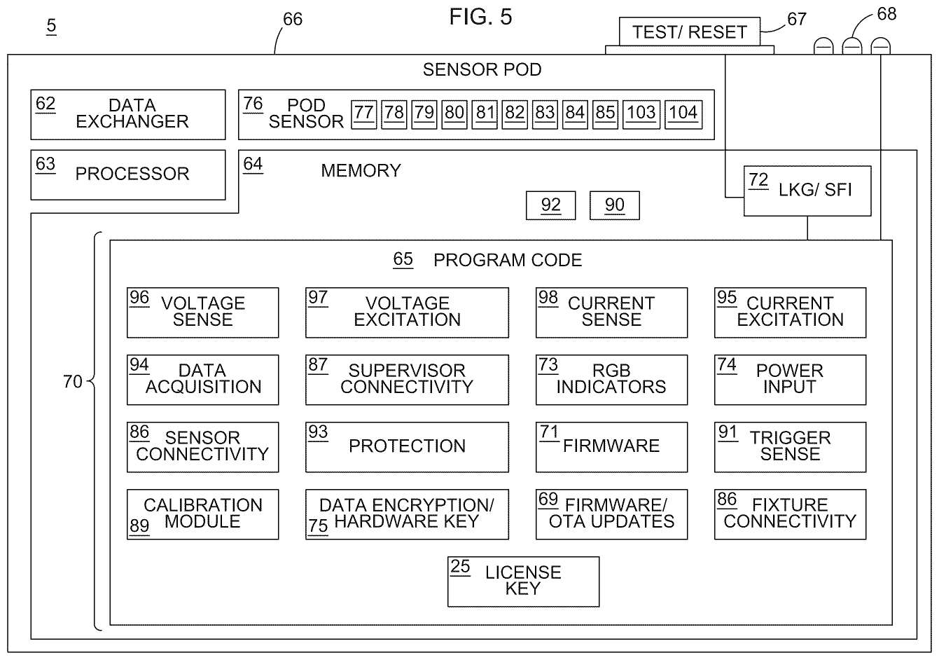

Now, with primary reference to FIG. 5, embodiments of the sensor pod program code (65) can include a sensor pod firmware update module (69) which implements sensor pod firmware updates of the sensor pod firmware (70). In particular embodiments, the pod firmware update module (69) operates to enable over-the-air updates. In particular embodiments, the pod program code (65) includes a last known good/signed factory image module (71). If a pod firmware update does not successfully install, the last known good/signed factory image module (71) can function to roll back to the last known good image (72) of the pod firmware (70). Operation of the sensor pod reset feature (67) actuates the last known good/signed factory image module (71) to copy the signed factory image of the sensor pod firmware (70) to a sensor pod read only memory boot address.

Again, with primary reference to FIG. 5, the pod computer program (65) can include a pod status indicator module (73) which functions to control operation of viewable or audible pod status indicators (68). As an illustrative example, the pod status indicators (68) can comprise light emitters coupled to the pod encasement (66). The light emitters can comprise light emitting diodes of various colors which can be operated independently or in various combinations or periodicity to indicate the status of the sensor pod (5), such as: power indication, error warning indication, ongoing test(s) indication, tests completed indication, cell sorting results or data status, such as: impedance measurements results indication, device matching or sorting results indication, and similar indication values.

Again, with primary reference to FIG. 5, the pod computer program (65) can further include a sensor pod power management module (74) operable to regulate power to the components of the sensor pod (5). The sensor pod (5) integrated into the distributed hardware architecture (2) can coordinate power from one source or from a plurality of sources individually, concurrently or in various combinations from a plurality of power sources including as illustrative examples: mains electric power, wall power, battery power, power over the ethernet, or the device (7) under test.

Again, with primary reference to FIG. 5, in particular embodiments, the pod computer program (65) can further include a data encryption-decryption module (75) operable to decrypt data from each of the plurality of sensor pods (5) and encrypt the data for transmission to the supervisor controller (4). The encryption-decryption of data can protect against reverse engineering of the pod firmware or any data associated with the impedance measurement(s) of a device(s) (7) under test, including as examples, settings, parameters, triggers. In particular embodiments, data associated with the impedance measurement(s) can be placed in random access memory with random memory address offsets to ensure that the specific data is not reverse engineered.

Now, with primary reference to FIGS. 1 and 5, embodiments of the sensor pod (5) can further include one or more pod sensors (76), or one or more pod sensors (76) communicatively coupled to the sensor pod (5), including one or more of: a current sensor (77), a voltage sensor (78), a temperature sensor (79), a pressure sensor (80), an acoustic emission sensor (81), an ultrasound sensor (82), an image capture sensor (83), a gas detection sensor (84), a humidity sensor (103), an infrared sensor (104), and an image reader (85).

Again, with primary reference to FIG. 5, embodiments of the pod program code (65) can further include a sensor connectivity module (86) which operates to validate that the sensor pod (5) has been connected to the device (7) under test. In the illustrative example of a battery device (7), the sensor connectivity module (86) can validate a four-point connection including connection to a pair of voltage connectors and a pair of current connectors. The sensor connectivity module (86) can further operate to assess the level of crosstalk interference between the battery connectors and determine that no crosstalk interference exists.

Again, with primary reference to FIG. 5, embodiments of the pod program code (65) can further include a supervisor connectivity module (87) which operates to enable the sensor pod (5) to receive communications from the supervisor controller (4) on measurement type, measurement settings, and measurement excitation signal requirements. The supervisor connectivity module (85) further operates to enable the sensor pod (5) to send results from the measurement of the device (7) under test along with associated metadata including sensor measurement data from the one or more pod sensors (5) including one or more of: voltage data, current data, temperature data, pressure data, acoustic emission data, ultrasound data, gas detection data, humidity data, infrared data, and device identification data.

Again, with primary reference to FIG. 5, embodiments of the pod program code (65) can further include a fixture connectivity module (88). In particular embodiments, the sensor pod (5) can be communicatively coupled to a fixture (6) configured to connect with the device (7) under test. The fixture connectivity module (86) can operate to validate the communication of the sensor pod (5) with the fixture (6) and the connections between the fixture (6) and the device (7) under test.

Again, with primary reference to FIG. 5, embodiments of the pod program code (65) can further include a calibration module (89) which operates to periodically correlate sensor pod data obtained by each pod sensor (5) against standardized calibration data (90) to ensure the accuracy and precision of the sensor pod measurements. In particular embodiments, the pod sensor (5) calibration may be done externally with manual checks and adjustments. In another embodiment, the sensor pod (5) be configured for in-situ or ex-situ calibration. See for example, U.S. Pat. No. 10,436,873 which discloses calibration of an impedance measurement device, hereby incorporated by reference in the entirety herein.

Again, with primary reference to FIG. 5, embodiments of the pod program code (65) can further include a trigger sense module (91) which correlates measurement instructions (16) to pre-selected parameter thresholds (92) which upon being achieved triggers a sensor pod (5) measurement of the device (7). As illustrative examples, the trigger can be initiated based on one or more measured parameters of the device (7) including: voltage change, current change temperature change, change in load current and pressure change. Once the trigger is activated, the sensor pod (5) will execute measurement instructions delivered by the supervisor controller (4).

Again, with primary reference to FIG. 5, embodiments of the pod program code (65) can further include a protection module (93). Devices under test can generate a sufficient amount of energy to cause catastrophic damage to the sensor pod (5) and/or serious injury to a user if the sensor pod (5) incorrectly connects to the device (7), such as, connecting a 160V battery pack to a sensor pod (5) configured to measure 48V or reversing the polarity of the device connections. Therefore, the protection module (93) operates to verify that the sensor pod (5) has a correct connection to the device (7) and the device voltage is within the operating range of the sensor pod (5). In particular embodiments, the use of field effect transistors or relays on device connections can operate to disconnect the device from the sensor pod (5).

Again, with primary reference to FIG. 5, embodiments of the pod program code (65) can further include a data acquisition module (94) which can operate to sample the voltage signal and current signals, and signals from other pod sensors (76) at an appropriate rate for data analysis and storage. The data acquisition module (94) should have an adjustable sample rate to ensure appropriate precision for the type of excitation signal is being applied to the device. For example, an AC signal based on HCSD or CTC using broadband measurements may require a 100 kHz sample rate. Excitation based on step group measurements can require different sample rates for each group being applied to the device. A DC-based excitation may require sample rates around 20 Hz or less.

Again, with primary reference to FIG. 5, the pod computer program (65) can further include a current excitation module (95) operable to excite a device (7) under test with a current excitation signal (15) based on impedance measurement instructions (14) sent by the supervisor controller (4). The current excitation signal (15a) can comprise an AC excitation signal configured to perform impedance measurements (17) over a broad frequency range. Illustrative examples of an AC excitation signal include: a galvanostatic excitation of EIS and/or IRIS signals, such as CSD, FST, HOST, CTC, or step-group. The current excitation module could also be configured to enable DC loads such as battery charge/discharge cycles, and DCIR.

Again, with primary reference to FIG. 5, the pod computer program (65) can further include voltage sense module (96) operable to implement capture of a voltage response signal (16b) of the device (7) under test. The voltage response signal (16b) can comprise the captured response to a current excitation signal (15a) of the device (7) under test or a measured voltage excitation signal (15b) of the device (7) under test or monitor voltage changes in a device (7). The voltage sense module (95) can operate to enable capture of voltage response signals (16b) at one or more specified sampling rates.

Again, with primary reference to FIG. 5, the pod computer program (65) can further include a voltage excitation module (97) operable to implement a voltage excitation signal (15b) of a device (7) under test based on the impedance measurement instructions (14) sent by the supervisor controller (4) to the sensor pod (5). The voltage excitation signal (15b) can comprise an AC signal configured for impedance measurements over a broad frequency range. As illustrative examples, the voltage excitation signal (15b) can comprise a potentiostatic excitation signal of the EIS and/or IRIS signals, such as CSD, FST, HOST, CTC, or step-group.

Again, with primary reference to FIG. 5, the pod computer program (65) can further include a current sense module (98) operable to implement capture of a current response signal (16a) of a device (7) under test. In particular embodiments, the current sensed can be in response to a voltage excitation (15b) or the measured current excitation signal (15a). The current sense module (97) can also operate to monitor current changes, as an example an independent load. The current sense module (98) can operate to measure an AC response at specified sampling rates. The current sense module (98) could also be configured to monitor changes in DC response at specified sampling rates.

The Fixture. Embodiments of the invention can include a fixture (6) configured to, or configurable in various derivations, to correspondingly to engage each of a wide variety of devices (7) to perform an impedance measurement. For example, the device (7) can be a battery having one of a variety of configurations, as illustrative examples: a prismatic configuration, cylindrical configuration, or pouch configuration. The placement of the battery tabs, the positive and negative connectors that distribute the electrical current of the battery, can also vary depending on the battery size and type. Thus, the fixture (6) can be one of a plurality of fixed configurations interchangeable depending on the configuration of the device (7) under test or can be one fixture (6) reconfigurable depending on the configuration of the device (7) under test. The fixture (6) can be configured to facilitate engagement to and release from the device (7). The fixture (6) can be a separate component or can be integrated into a sensor pod (5). A fixture (6) can be communicatively coupled to each of the sensor pods (5) or combinations of sensor pods (5) which may be connected in series, in parallel, or in parallel and in series, or combinations thereof, depending on the application. The fixture (6) can deliver the excitation signal (15) to the device (7) under test and capture the response signal (16) from the device (7) under test.

The Device. The device (7) under test can be connected directly to or indirectly through the fixture (6) to one or more pods (5). While the illustrative examples of the device (7) under test comprise battery packs, battery modules, strings of battery cells, or battery cells, or battery components, whether during manufacture or integrated into other systems such as battery management systems; this is not intended to preclude application of embodiments of inventive hardware architecture (2) to perform impedance measurement, or other measurements, of other systems, devices or objects, as illustrative examples: solar panels, solar cells, solar cell components, fuel cells, ultracapacitors, dielectric materials, concrete, biological systems, biological components, or biological objects such human or animal body parts, organs, glands, tissues, membranes, fluids, or isolated biological cells, and cell culture growth medium.

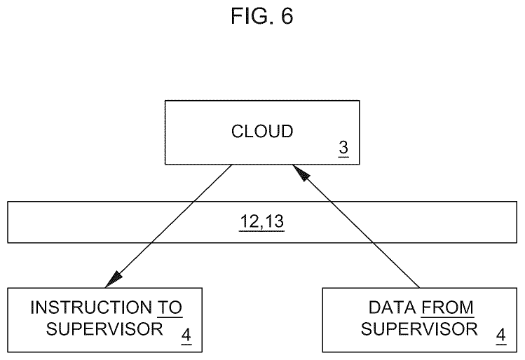

Cloud Communication. Now, with primary reference to FIG. 6 which generally depicts the flow of data over a network (12, 13) from the cloud (3) to the supervisor controller (4). The flow of data from the cloud (3) to the supervisor controller (4) can include impedance measurement instructions (14), or other instructions, to test one or more devices (7). The supervisor controller (4) sends data packets for analysis to the cloud (3). The data packets sent over the network (12, 13) from the supervisor controller (4) to the cloud (3) can include a response to the impedance measurement instructions (14) sent from the cloud (3) to the supervisor controller (4).

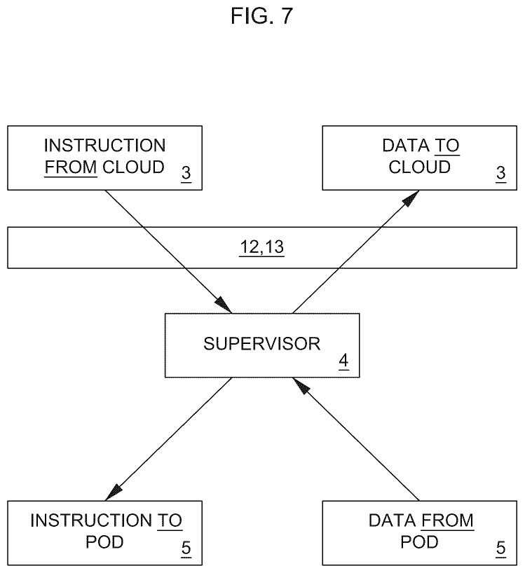

Supervisor Controller Communication. Now with primary reference to FIG. 7, which depicts the flow of data sent by the supervisor controller (4) to one or more sensor pods (5). The flow of data from the supervisor controller (4) to one or more sensor pods (5) can include the impedance measurement instructions (14), or other instructions, sent over the network (12, 13) from the cloud (3) to the supervisor controller (4) to be associated with each one of a plurality of sensor pods (5) communicatively coupled the supervisor controller (4). The supervisor controller (4) receives response data back from each of a plurality of sensor pods (5) and sends the response data over the network (12, 13) for analysis to the cloud (3).

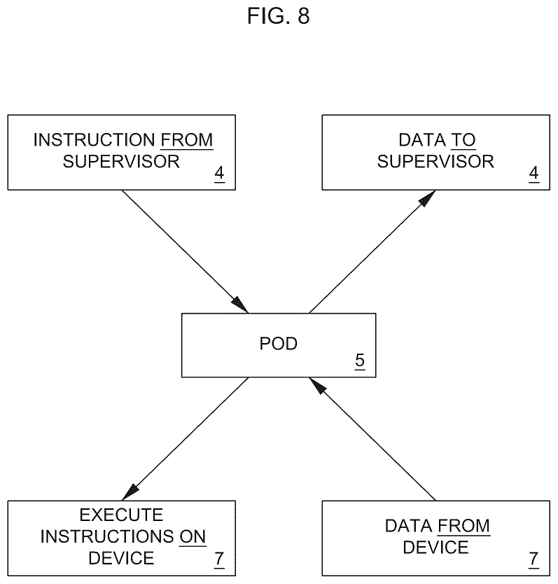

Sensor Pod Communication. Now, with primary reference to FIG. 8, each sensor pod (5) executes the impedance measurement instructions (14), or other test instructions, received from the supervisor controller (4) on the device (7) under test, whether directly or through the fixture (6). The sensor pod (5) acquires a response signal (16) from the device (7) under test. The sensor pod (5) transmits the response signal (16) captured from the device (7) under test to the supervisor controller (4).

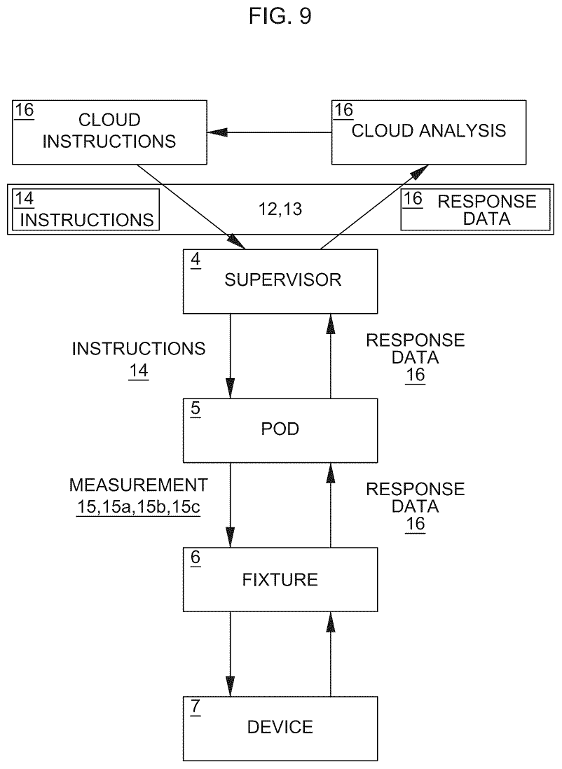

Overall Operation of the Distributed Impedance Measurement System. Now, with primary reference to FIG. 9, in high level overview, the cloud (3) operates to send impedance measurement instructions (14) over a network (12, 13) to the supervisor controller (4). The impedance measurement instructions (14) can be created based on one or more of: AI/ML algorithms, device characterization data (device type, device voltage, device current, device load, device charge, device discharge, device temperature, device pressure, device acoustic emissions, device ultrasound emissions), prior device measurements, calibration standards, and lookup tables. The impedance measurement instructions (14), or other test instructions, can be received by the supervisor controller (4) which operates to channel each of a plurality of impedance measurement instructions (14) to a corresponding one of a plurality of sensor pods (5). Each of the plurality of sensor pods (5) communicatively coupled to a supervisor controller (4) receives the impedance measurement instructions (14), or other test measurement instructions, from the supervisor controller (4) and executes the impedance measurement instructions (14), or other test measurement, on the device (7) under test. During implementation of the impedance measurement instructions (14), or other test measurement, the sensor pod (5) captures the response signal (16) from the device (7) under test and transmits the excitation signal (15) and the response signal (16) to the supervisor controller (4). The supervisor controller (4) then operates to send the response signal (16) (whether as raw response data, processed response data or a combination thereof) back to the cloud (3) for analysis, which analysis can provide feedback to further augment creation of the next set of impedance measurement instructions (14), or other test instructions, sent over the network (12, 13) to the supervisor controller (4).

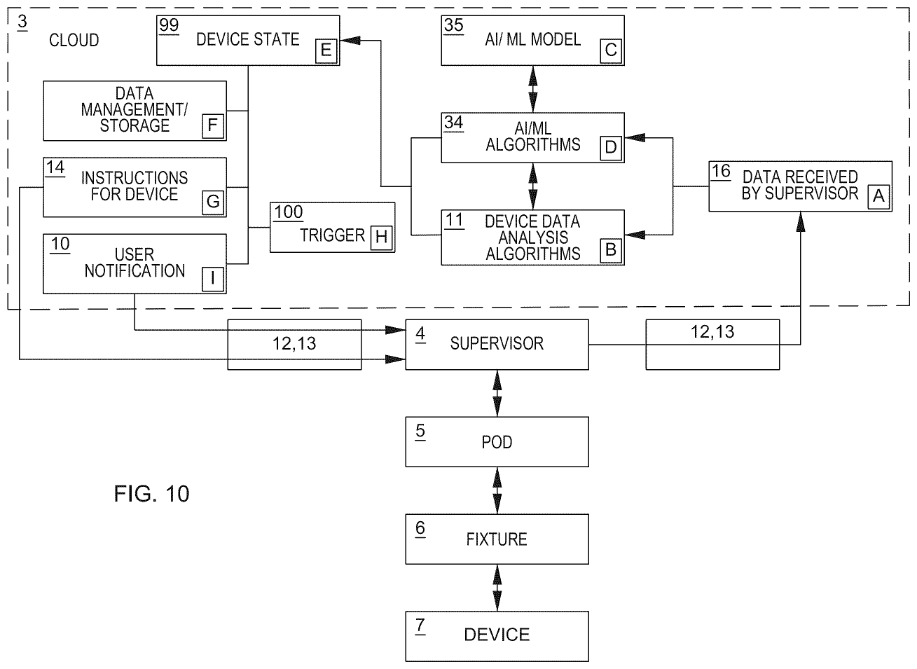

Cloud Operation. Now, with primary reference to FIG. 10, the cloud (3) operation enclosed by broken line includes receiving response data (16) from each of a plurality of devices (7) under test over a network (12, 13), such as the Internet, from the supervisor controller (4) (Block A). The cloud (3) can preprocess and process the response data (16) using one or more of device data analysis algorithms (11) (Block B). Illustrative examples of data analysis algorithms (11) can include impedance spectrum algorithms useful to process AC impedance measurement response time records to determine impedance as a function of the excitation signal frequencies (15c′ . . . ) utilized in the excitation signal (15) to the device (7) under test include, but are not limited to, harmonic compensated synchronous detection (HCSD), fast summation transformation (FST), generalized fast summation transformation (GFST), frequency cross talk compensation (FCTC), time cross talk compensation (TCTC), harmonic orthogonal synchronous transformation (HOST), step group, and combinations thereof. See, for example, U.S. Pat. Nos. 7,688,036; 7,395,163 B1; 7,675,293 B2; 8,150,643 B1; 8,352,204 B2; 8,762,109 B2; 8,868,363 B2; and 9,244,130 B2, and United States Patent Publications Nos. 2011/0270559 A1; 2014/0358462 A1; and 2017/0003354 A1, each hereby incorporated by reference herein, which describe the implementation of one more of the data analysis algorithms (11). In particular embodiments, an artificial intelligence/machine learning model (35) can be created by using the sensor pod data (16) (Block C) with known results as “training data” for an artificial intelligence/machine learning algorithm (34) (Block D). In particular embodiments, the cloud (3) can further operate to interpret the results of the data analysis and draw conclusions regarding a device state (99) (Block E) including as illustrative examples SOH, SOS, RUL, EOL, FUA, SUA, device screening, device binning, device matching, and combinations thereof. In particular embodiments, the cloud (3) can further operate to manage and store raw data, pre-processed data, and processed data (Block F). This can include one or more of: storing the data in a database, cloud storage, or other nodes within the network (12, 13), and implementing backup and recovery strategies to protect against data loss. The cloud (3) can then operate to generate new impedance measurement instructions (14), or other test instructions based on the conclusion involving the device state (Block G). The impedance measurement instructions (14), or other test instructions, to be implemented in measurement of the device (7) can be initiated by the cloud (3) (Block H). In particular embodiments, initiation can be based on one or more of: occurrence of a trigger (100), an abnormality in the device response data, client computer request. In particular embodiments the device state can be provided as user notifications (Block I) to the supervisor controller (4) through activation of one or more viewable or audible supervisor controller status indicators (46, 51) or the sensor pod (5) through activation of one or more viewable or audible sensor pod indictors (68), or through use of a client user portal (24) to a client computer (18). The user notification (101) to a client computer may take the form of one or more screen displays (22) of the graphical user interface (21) including one or more of: dashboards, displays, visualizations, videos, reports, or viewable content that identifies key findings or trends in the data relating to the device state (99).

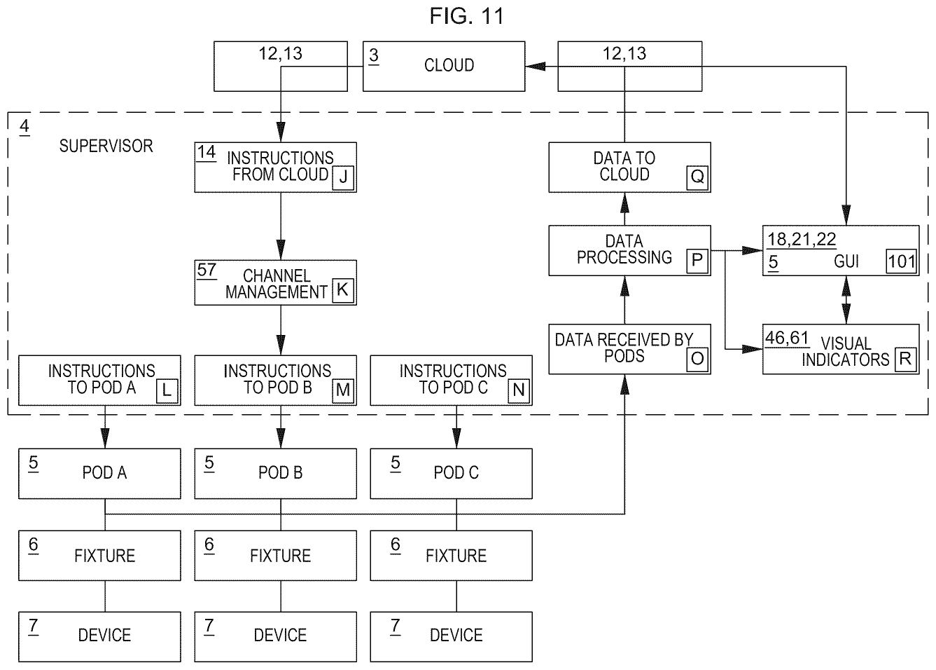

Supervisor Controller Operation. Now, with primary reference to FIG. 11, the supervisor controller (4) operation enclosed by broken line includes receipt of one or a plurality of impedance measurement instructions (14), or other test instructions. over a network (12, 13), such as the Internet (Block J). Each supervisor controller (4) can control one or a plurality of sensor pods (5). In the example of one supervisor controller (4) controlling a plurality of pods (5), the supervisor controller (4) implements channel management (57) to ensure that each of the plurality of impedance measurement instructions (14), or other test instructions, received from the cloud (3) are correspondingly associated correctly with one of the plurality of sensor pods (5) (Block K). In particular embodiments, the channel management (57) can be implemented by the cloud (3). The supervisor controller (4) can by implementation of channel management (57) deliver each of the plurality of impedance measurement instructions (14), or other test instructions, to a corresponding one of the plurality of sensor pods (5): in the example, Instruction to Pod A, Instruction to Pod B, and Instruction to Pod C (Blocks L, M, N). The impedance measurement instructions (14), or other test instructions, can be the same for each one of a plurality of sensor pods (5). Alternatively, each of a plurality of impedance measurement instructions (14) can be different between each of a plurality of sensor pods (5). For example, the impedance measurement instructions can include different frequency ranges, different test sequences, or different metadata requirements. When each of the plurality of sensor pods (5) have executed the impedance measurement instructions (14) to generate the excitation signal (15) to excite the device (7) under test and have captured the corresponding response signal (16) the collected response data can be transmitted to and received by the supervisor controller (4) (Block O). In particular embodiments, the supervisor controller (4) can operate a data processing module (58) to determine the validity of the response data (16) (Bock P). If the response data (16) is determined to be invalid, due to improper connections or noisy output, as examples, the supervisor controller (4) can further operate to instruct the appropriate sensor pod (5) to repeat the impedance measurement, modify the impedance measurement of the device (7) or provide notice to the client computer (18) of the invalidity of the response data. In particular embodiments, the supervisor controller (4) can further process raw response data to reduce file size. The supervisor controller (4) can then operate to send response data (16) (whether raw response data or processed response data) to the cloud for analysis (Block Q). The supervisor controller (4) can further operate to actuate supervisor controller status indicators (46, 51) to indicate the status of the supervisor controller (4) (Block R). In particular embodiments, the supervisor controller (4) can provide user notifications (101) (Block S) through use of the client user portal (24) to a client computer (18) (Block S). The user notification (101) to a client computer (18) may take the form of one or more screen displays (22) of the graphical user interface (21) including one or more of: dashboards, displays, visualizations, videos, reports, or viewable content that identifies key findings or trends in the data relating to the supervisor controller or the device state (99).

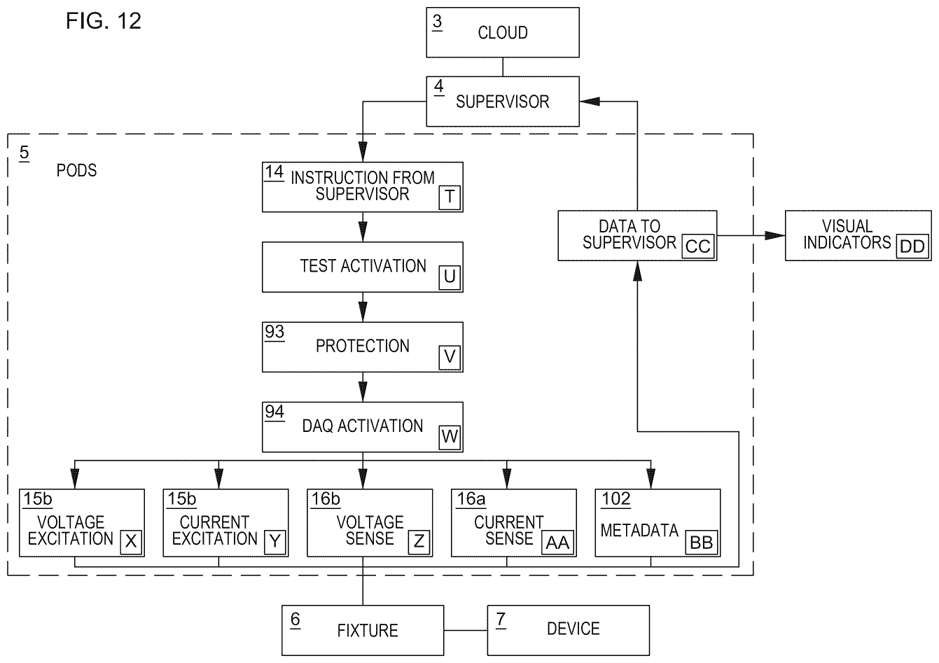

Sensor Pod Operation. Now, with primary reference to FIG. 12, the sensor pod (5) operation enclosed by broken line includes receiving impedance measurement instruction (14), or other test instructions, from the supervisor controller (4) (Block T). The sensor pod (5) can implement the impedance measurement instruction (14), or other test instructions, immediately upon receipt, or can implement the impedance measurement instruction, or other test instructions, upon occurrence of a trigger (100) (Block U). The sensor pod (5) can then initiate the protection module (93) to verify that the sensor pod (5) has a correct connection to the device (7) under test and the device voltage is within the operating range of the sensor pod (5) (Block V). The sensor pod (5) can then initiate the data acquisition module (94) to sample the voltage signal and current signals at an appropriate rate for data analysis and storage (Block W). The sensor pod (5) then initiates the impedance measurement instructions (14), or other test instructions, of the device (7) (examples include generating a voltage excitation signal (15b) (Block X), a current excitation signal (15a) (Block Y). The sensor pod (5) can then operate to capture the response signal (16) from the device (7) under test (examples including a voltage response (16b) (Block Z), a current response (Block AA), and capture other metadata (102) based on sensor signals from pod sensors (5) associated with the device (7) under test, as examples, device identification, device temperature, device pressure, acoustic emissions, ultrasound emissions (Block BB). The response data (16) can then be sent to the supervisor controller (4) (Block CC). The sensor pod (5) can further actuate pod status indicators (68) to indicate the status of the supervisor controller (4) (Block DD).

As can be easily understood from the foregoing, the basic concepts of the present invention may be embodied in a variety of ways. The invention involves numerous and varied embodiments of a distributed impedance measurement system (1) and methods for making and using such distributed impedance measurement system (1) including the best mode.

As such, the particular embodiments or elements of the invention disclosed by the description or shown in the figures or tables accompanying this application are not intended to be limiting, but rather exemplary of the numerous and varied embodiments generically encompassed by the invention or equivalents encompassed with respect to any particular element thereof. In addition, the specific description of a single embodiment or element of the invention may not explicitly describe all embodiments or elements possible; many alternatives are implicitly disclosed by the description and figures.

It should be understood that each element of an apparatus or each step of a method may be described by an apparatus term or method term. Such terms can be substituted where desired to make explicit the implicitly broad coverage to which this invention is entitled. As but one example, it should be understood that all steps of a method may be disclosed as an action, a means for taking that action, or as an element which causes that action. Similarly, each element of an apparatus may be disclosed as the physical element or the action which that physical element facilitates. As but one example, the disclosure of a “measurement” should be understood to encompass disclosure of the act of “measuring”—whether explicitly discussed or not—and, conversely, were there is a disclosure of the act of “measuring”, such a disclosure should be understood to encompass disclosure of a “measurement” and even a “means for measuring”. Such alternative terms for each element or step are to be understood to be explicitly included in the description.

In addition, as to each term used it should be understood that unless its utilization in this application is inconsistent with such interpretation, common dictionary definitions should be understood to be included in the description for each term as contained in the Random House Webster's Unabridged Dictionary, second edition, each definition hereby incorporated by reference.

All numeric values herein are assumed to be modified by the term “about”, whether or not explicitly indicated. For the purposes of the present invention, ranges may be expressed as from “about” one particular value to “about” another particular value. When such a range is expressed, another embodiment includes from the one particular value to the other particular value. The recitation of numerical ranges by endpoints includes all the numeric values subsumed within that range. A numerical range of one to five includes for example the numeric values 1, 1.5, 2, 2.75, 3, 3.80, 4, 5, and so forth. It will be further understood that the endpoints of each of the ranges are significant both in relation to the other endpoint, and independently of the other endpoint. When a value is expressed as an approximation by use of the antecedent “about,” it will be understood that the particular value forms another embodiment. The term “about” generally refers to a range of numeric values that one of skill in the art would consider equivalent to the recited numeric value or having the same function or result. Similarly, the antecedent “substantially” means largely, but not wholly, the same form, manner or degree and the particular element will have a range of configurations as a person of ordinary skill in the art would consider as having the same function or result. When a particular element is expressed as an approximation by use of the antecedent “substantially,” it will be understood that the particular element forms another embodiment.

Moreover, for the purposes of the present invention, the term “a” or “an” entity refers to one or more of that entity unless otherwise limited. As such, the terms “a” or “an”, “one or more” and “at least one” can be used interchangeably herein.

Further, for the purposes of the present invention, the term “coupled” or derivatives thereof can mean indirectly coupled, coupled, directly coupled, connected, directly connected, or integrated with, depending upon the embodiment.

Additionally, for the purposes of the present invention, the term “integrated” when referring to two or more components means that the components (i) can be united to provide a one-piece construct, a monolithic construct, or a unified whole, or (ii) can be formed as a one-piece construct, a monolithic construct, or a unified whole. Said another way, the components can be integrally formed, meaning connected together so as to make up a single complete piece or unit, or so as to work together as a single complete piece or unit, and so as to be incapable of being easily dismantled without destroying the integrity of the piece or unit.

Thus, the applicant(s) should be understood to claim at least: i) the distributed impedance measurement system herein disclosed and described, ii) the related methods disclosed and described, iii) similar, equivalent, and even implicit variations of each of these devices and methods, iv) those alternative embodiments which accomplish each of the functions shown, disclosed, or described, v) those alternative designs and methods which accomplish each of the functions shown as are implicit to accomplish that which is disclosed and described, vi) each feature, component, and step shown as separate and independent inventions, vii) the applications enhanced by the various systems or components disclosed, viii) the resulting products produced by such systems or components, ix) methods and apparatuses substantially as described hereinbefore and with reference to any of the accompanying examples, x) the various combinations and permutations of each of the previous elements disclosed.

The background section of this patent application, if any, provides a statement of the field of endeavor to which the invention pertains. This section may also incorporate or contain paraphrasing of certain United States patents, patent applications, publications, or subject matter of the claimed invention useful in relating information, problems, or concerns about the state of technology to which the invention is drawn toward. It is not intended that any United States patent, patent application, publication, statement or other information cited or incorporated herein be interpreted, construed or deemed to be admitted as prior art with respect to the invention.

The claims set forth in this specification, if any, are hereby incorporated by reference as part of this description of the invention, and the applicant expressly reserves the right to use all of or a portion of such incorporated content of such claims as additional description to support any of or all of the claims or any element or component thereof, and the applicant further expressly reserves the right to move any portion of or all of the incorporated content of such claims or any element or component thereof from the description into the claims or vice-versa as necessary to define the matter for which protection is sought by this application or by any subsequent application or continuation, division, or continuation-in-part application thereof, or to obtain any benefit of, reduction in fees pursuant to, or to comply with the patent laws, rules, or regulations of any country or treaty, and such content incorporated by reference shall survive during the entire pendency of this application including any subsequent continuation, division, or continuation-in-part application thereof or any reissue or extension thereon. The elements following an open transitional phrase such as “comprising” may in the alternative be claimed with a closed transitional phrase such as “consisting essentially of” or “consisting of” whether or not explicitly indicated the description portion of the specification.

Additionally, the claims set forth in this specification, if any, are further intended to describe the metes and bounds of a limited number of the preferred embodiments of the invention and are not to be construed as the broadest embodiment of the invention or a complete listing of embodiments of the invention that may be claimed. The applicant does not waive any right to develop further claims based upon the description set forth above as a part of any continuation, division, or continuation-in-part, or similar application.

1. A distributed impedance measurement system, comprising:
a cloud-based network of remote servers including a non-transitory computer readable media containing a cloud program code served to implement impedance measurement algorithms to measure impedance of a plurality of devices under test;
a supervisor controller communicatively coupled to said cloud, said supervisor controller operable to:
receive said impedance measurement instructions to measure impedance of said plurality of devices under test;
concurrently associate each of said impedance measurement instructions with one of said plurality of devices under test;
concurrently associate each of a plurality of response signals based on said impedance measurement instructions with one of said plurality of devices under test; and
one or more sensor pods communicatively coupled to said supervisor controller, each of said one or more sensors pods operable to:
receive said impedance measurement instructions associated with one of said plurality of devices under test from said supervisor;
execute an excitation signal based on said impedance measurement instructions;
receive a response signal resulting from said excitation signal;
send said response signal to said supervisor.

2. The system of claim 1, further comprising a fixture communicatively coupled to each of said one or more sensor pods, said fixture configured to operably engage one of said plurality of devices under test to deliver said excitation signal to said device under test and capture said response signal from said device under test.

3-6. (canceled)

7. The system of claim 1, wherein a voltage of one of said plurality of devices under test falls within voltage limits of one of said sensor pods and said current excitation signal of said one of said plurality of devices under test falls outside of current limits of said one of said sensor pods.

8. The system of claim 7, wherein said plurality of said sensor pods comprises a plurality of sensor pods connected in parallel.

9. The system of claim 1, wherein said current excitation signal of one of said plurality of devices under test falls within current limits of said one of said plurality of sensor pods and the voltage of said one of said plurality of devices under test falls outside of voltage limits of said one of said sensor pods.

10. The system of claim 9, wherein a plurality of said sensor pods connected in series.

11. The system of claim 1, wherein a current excitation signal of one of said plurality of devices under test falls outside of current limits of said one of said plurality of sensor pods and a voltage of said one of said plurality of devices under test falls outside of voltage limits of said one of said plurality of sensor pods.

12. The system of claim 11, wherein a plurality said sensor pods connected in parallel and pairs of said plurality said sensor pods connected in parallel further connected in series.

13-14. (canceled)

15. The system of claim 1, further comprising a pod sensor associated with each of said one or more sensor pods, said pod sensor configured to sense a device identifier associated with said one or more devices under test.

16. The system of claim 1, further comprising a pod sensor associated with each of said one or more sensor pods, said pod sensor comprising one or more of: a current sensor, a voltage sensor, a temperature sensor, a pressure sensor, an acoustic emission sensor, an ultrasound sensor, an image capture sensor, a humidity sensor, an infrared sensor, and an image reader.

17. The system of claim 1, further comprising a data exchanger associated with each of said one or more sensor pods, said data exchanger operable to exchange data with said supervisor controller.

18. The system of claim 1, wherein each of said one or more sensor pods includes a processor communicatively coupled to a non-transitory computer readable media containing a sensor pod program.

19-22. (canceled)

23. The system of claim 18, wherein said sensor pod program includes a voltage excitation module operable to deliver a voltage excitation signal of said device under test.

24. The system of claim 18, wherein said sensor pod program includes a current excitation module operable to deliver a current excitation signal of said device under test.

25. The system of claim 18, wherein said sensor pod program includes a calibration module operable to calibrate an impedance measurement of said device under test.

26. The system of claim 18, wherein said sensor pod program includes a voltage sense module operatable to capture a voltage response of said device under test.

27. The system of claim 18, wherein said sensor pod program includes a current sense module to capture a current response of said device under test.

28-45. (canceled)

46. The system of claim 1, further comprising a reset feature disposed on each of said one or more of said supervisor controllers, said reset feature actuates a factory image restore module containing a factory certified image or a last known good image of a firmware, said image restore feature copies said factory certified image or said last known good image to a boot code.

47. The system of claim 1, further comprising a supervisor controller data exchanger operable to transfer data between the cloud and the supervisor controller.

48. The system of claim 1, wherein each of said one or more supervisor controllers includes a supervisor controller processor communicatively coupled to a non-transitory computer readable media containing a supervisor controller program.

49-50. (canceled)

51. The system of claim 48, wherein said supervisor controller program includes a pod power delivery module operable to regulate power to each of one or more sensor pods from the one or the plurality of power sources to implement operation of each of the plurality of sensor pods.

52. The system of claim 48, wherein said supervisor controller program includes a cloud data exchanger operable to transfer information between said supervisor controller and said cloud.

53. The system of claim 52, wherein said supervisor controller program includes sensor pod data exchanger operable to transfer information between said supervisor controller and said one or more sensor pods.

54. The system of claim 53, wherein said supervisor controller program includes a channel management module operable to enable concurrent or staggered transfer of data between said supervisor controller a plurality of sensor pods.

55-59. (canceled)
